(19) United States
(12) Patent Application Publication
(10) Pub. No.: US 2022/0375631 A1
(43) Pub. Date: Nov. 24, 2022

(54) PHYSICAL VAPOR DEPOSITION OF CERAMIC COATINGS ON ZIRCONIUM ALLOY NUCLEAR FUEL RODS

(71) Applicant: Westinghouse Electric Company LLC, Cranberry Township, PA (US)

(72) Inventors: Magnus NORLEN, Västerås (SE); Jonathan WRIGHT, Västerås (SE); Edward J. LAHODA, Edgewood, PA (US); Magnus LIMBACK, Västerås (SE); Jorie L. WALTERS, Columbia, SC (US); Javier E. ROMEO, Columbia, SC (US); Benjamin R. MAIER, Pittsburgh, PA (US)

(73) Assignee: Westinghouse Electric Company LLC, Cranberry Township, PA (US)

(21) Appl. No.: 17/753,744

(22) PCT Filed: Sep. 12, 2020
(86) PCT No.: PCT/US2020/050592

§ 371 Date: Mar. 14, 2022

Related U.S. Application Data
(60) Provisional application No. 62/899,977, filed on Sep. 13, 2019.

(51) Int. Cl. G21C 3/07; C23C 14/06; C23C 14/02

(52) U.S. Cl. CPC G21C 3/07; C23C 14/0641; C23C 14/025

(57) ABSTRACT

A nuclear fuel cladding tube is described herein that includes a zirconium alloy tube having an outer wear and oxidation resistant ceramic coating selected from the group consisting of CrN, Cr₂N, CrWN, CrZrN, and combinations thereof. The cladding may have an intermediate layer formed between the tube and the outer ceramic coating. The intermediate layer may be selected from the group consisting of Ta, W, Mo, Nb, and combinations thereof. Both the intermediate layer and the outer ceramic coating may be deposited by physical vapor deposition.

### CROSS-REFERENCE TO RELATED APPLICATION

This application claims the benefit of 62/899,977, filed Sep. 13, 2019 entitled “PHYSICAL VAPOR DEPOSITION OF CERAMIC COATINGS ON ZIRCONIUM ALLOY NUCLEAR FUEL RODS,” the contents of which are incorporated by reference herein.

### BACKGROUND

### 1. Field.

The present application relates to nuclear fuel claddings, and more particularly to zirconium alloy tubes with outer ceramic coatings.

### 2. Description of the Prior Art

In a typical nuclear reactor, the reactor core includes a large number of fuel assemblies, each of which is composed of a plurality of elongated fuel rods. The fuel rods each contain nuclear fuel fissile material, usually in the form of a stack of nuclear fuel pellets surrounded by a gas, such as He. The fuel rods have a cladding that acts as a containment for the fissile material.

Light water reactors use water as a coolant method and as a neutron moderator. There are the two types of light water reactors, pressurized water reactors (PWR) and boiling water reactors (BWR). In these types of reactors, the cladding tubes are typically made of a zirconium alloy. Zirconium alloys rapidly react with steam at temperatures of 1100° C. and above to form zirconium oxide and hydrogen. In the environment of a nuclear reactor, the hydrogen produced from that reaction would dramatically pressurize the reactor and would eventually leak into the containment or reactor building leading to potentially explosive atmospheres and to potential hydrogen detonations, which could lead to fission product dispersion outside of the containment building. Maintaining the fission product boundary is of critical importance.

Hard facing coatings on fuel cladding materials are being developed to counteract fuel failure from debris fretting. One issue that has arisen is the stability of these coatings under conditions which prevail inside the core of a BWR.

It has been proposed that fuel rod cladding can be coated with materials to prevent exterior corrosion as disclosed in U.S. Pat. Nos. 9,336,909 and 8,971,476, the relevant portions of which are incorporated herein by reference. Coated Zr cladding overcomes one of the major issues associated with beyond design basis accidents: excessive oxidation above 1200° C. Coating with just chromium (Cr) produces a low melting eutectic between Zr and Cr at lower than the 1333° C. temperature because of the other components of the Zr alloy, To get around this issue, an initial niobium (Nb) coating has been proposed.

Methods using cold spray to deposit Cr coatings and Nb/Cr coatings onto zirconium alloy rods to improve the corrosion resistance in both normal operating conditions and off-normal operating conditions have been described. The intermediate Nb layer in these coatings eliminates eutectic formation between Cr and Zr at temperature higher than 900° C. The Cr coatings have been previously identified as good accident tolerant coatings in high temperature steam and air.

U.S. Patent Application US 2014/0254740 discloses efforts to apply metal oxides, ceramic materials, or metallic alloys that contain chromium to a zirconium alloy cladding tube using a thermal spray, such as a cold spray technique wherein powderized coating materials are deposited with substantial velocity on a substrate in order to plastically deform the particles into a flattened, interlocking material that forms a coating. See U.S. Pat. No. 5,302,414.

However, Cr is not suitable for boiling water reactor (BWR) chemistries or in low H2 pressurized water reactor (PWR) chemistry.

Ceramics and in particular pure or modified chromium nitrides have been identified which are suitable for use in BWR chemistry. Ceramic coatings are also more wear resistant. However, these compounds containing Cr may also react with Zr alloys at temperatures that occur under accident conditions. BWRs also suffer from fuel failures due to debris in the coolant.

### SUMMARY

The following summary is provided to facilitate an understanding of some of the innovative features unique to the embodiments disclosed and is not intended to be a full description. A full appreciation of the various aspects of the embodiments can be gained by taking the entire specification, claims, abstract and drawings as a whole.

A nuclear fuel cladding tube is described herein that includes a zirconium alloy tube having an outer wear and oxidation resistant ceramic coating selected from the group consisting of CrN, Cr₂N, CrWN, CrZrN, and combinations thereof. The ceramic coating in various aspects is deposited by physical vapor deposition and may he between 0.1 and 30 μm (micrometer) in thickness.

In various aspects, the cladding may further include an intermediate layer formed between the tube and the outer ceramic coating. The intermediate layer may be selected from the group consisting of Ta, W, Mo, Nb, and combinations thereof. The intermediate layer may in various aspects be deposited by physical vapor deposition and may be between 0.01 and 10 μm in thickness.

Also described herein is a method for making a nuclear fuel cladding. The method generally includes the steps of providing a zirconium alloy cladding tube having an interior for housing fissile material and an exterior surface, and depositing a ceramic wear and oxidation resistant coating on the exterior surface of the cladding tube selected from the group consisting of CrN, Cr₂N, CrWN, CrZrN, and combinations thereof.

The method may further include the step of depositing an intermediate layer on the exterior surface of the cladding tube prior to depositing the ceramic coating. The intermediate layer may be selected from the group consisting of Ta, W, Mo, Nb, and combinations thereof. In various aspects, the intermediate layer is deposited by physical vapor deposition, preferably to a thickness between 0.01 and 10 μm.

### BRIEF DESCRIPTION OF THE DRAWINGS

The characteristics and advantages of the present disclosure may be better understood by reference to the accompanying figures.

FIG. 1 is a graph showing temperatures at the inlet, middle and outlet of the test autoclave during the first exposure of coated cladding samples.

FIG. 2 is a graph showing zoomed in temperatures of the graph of FIG. 1 during the first exposure.

FIG. 3 is a graph showing the conductivity and temperature at the middle of the test autoclave during the first exposure.

FIG. 4 is a graph showing the pressure and temperature at the middle of the test autoclave during the first exposure.

FIG. 5 is a graph showing the oxygen level and temperature at the middle of the test autoclave during the first exposure.

FIG. 6 is a graph showing the temperatures at the inlet, middle and outlet of the test autoclave during the second exposure.

FIG. 7 is a graph showing the zoomed in temperatures of the graph of FIG. 6 during the second exposure.

FIG. 8 is a graph showing the conductivity and temperature at the middle of the test autoclave during the second exposure.

FIG. 9 is a graph showing the pressure and temperature at the middle of the test autoclave during the second exposure.

FIG. 10 is a graph showing the oxygen level and temperature at the middle of the test autoclave during the second exposure.

### DESCRIPTION OF THE PREFERRED EMBODIMENTS

As used herein, the singular form of “a”, “an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

In the present application, including the claims, other than where otherwise indicated, all numbers expressing quantities, values or characteristics are to be understood as being modified in all instances by the term “about.” Thus, numbers may be read as if preceded by the word “about” even though the term “about” may not expressly appear with the number. Accordingly, unless indicated to the contra, any numerical parameters set forth in the following description may vary depending on the desired properties one seeks to obtain in the compositions and methods according to the present disclosure. At the very least, and not as an attempt to limit the application of the doctrine of equivalents to the scope of the claims, each numerical parameter described in the present description should at least be construed in light of the number of reported significant digits and by applying ordinary rounding techniques.

Any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

A single or duplex accident tolerant coating comprising an outer corrosion resistant coating layer of CrN, Cr₂N, CrWN or CrZrN, or mixtures thereof. An intermediate layer may he applied prior to deposition of the outer coating layer. The intermediate layer in various aspects, may be one or a combination of Ta, W. Mo or Nb and is included to prevent the Cr/Zr eutectic formation and enable superior high temperature performance. The outer coating is designed to provide both oxidation and wear resistance. Both the outer coating layer and the intermediate layer may he applied using a physical vapor deposition (PVD) process. The intermediate layer of one or a combination of Ta, W, Mo and Nb may be applied to a thickness ranging from 0.01 to 10 μm, followed by deposition, again by a PVD process, of the wear and oxidation resistant outer coating layer of CrN, Cr₂N, CrWN or CrZrN or mixtures thereof, at a thickness ranging from 0.1 to 30 μm. The ratio of metallic elements Cr, W and Zr is variable within these coatings.

PVD is especially preferred for the intermediate layer deposition because it can apply a very thin coating of Ta, W, Mo or Nb, which can minimize the overall thickness of the dual coating.

The present disclosure identifies both wear and oxidation resistance coatings for LWR applications which can be applied as either a single layer or with an interlayer of one or a combination of Mo, Ta, W or Nb.

Several physical vapor deposition processes are known in the art for depositing thin layers of materials, such as particles, to a substrate and may he used to apply one or both of the outer coating and intermediate layers. PVD may he characterized as a collective set of vacuum deposition techniques consisting of three fundamental steps: (1) vaporization of the material from a solid source assisted by high temperature vacuum or gaseous plasma; (2) transportation of the vapor in vacuum or partial vacuum to the substrate surface; and, (3) condensation onto the substrate to generate thin films.

The most common of the PVD coating processes are evaporation (typically using cathodic arc or electron beam sources), and sputtering (using magnetic enhanced sources or “magnetrons”, cylindrical or hollow cathode sources). All of these processes occur in vacuum at working. pressure (typically 1 to 0.01 Pa (10⁻² to 10^{31 4} mbar)) and generally involve bombardment of the substrate to be coated with energetic positively charged ions during the coating process to promote high density. Additionally, reactive gases may be introduced into the vacuum chamber during metal deposition to create various compound coaling compositions. The result is a very strong bond between the coating and the substrate and tailored physical and properties of the deposited layer.

The ceramic single layers provide wear resistance against debris fretting which causes fuel failures in commercial nuclear plants. They may also be beneficial for reducing hydrogen pickup and thus enabling enhanced flexibility and/or higher burnup.

While a single layer of the outer coating only will provide some accident tolerance, adding a second layer in the form of the intermediate layer positioned between the Zr alloy cladding and the outer coating will prevent the Cr/Zr eutectic at high temperatures. The duplex structure applied by PVD with the addition of the bond layer of Mo, Ta, W or Nb can improve the accident tolerance of the ceramic coatings since the identified chromium nitride based materials have a tendency to decompose to the Cr metal and nitrogen gas. For example both CrN and Cr₂N decomposes to chromium metal and nitrogen gas at relatively low temperatures¹. The Cr left behind could then form a eutectic with Zr at about 1333° C. ¹ See, Data from SpMCBN refractory alloy database, obtained from http//www.crct.polymtl.ca/fact/Documentation/SPMCBN/SPMCBN List.htm. From “Table 2: List of phases for BINARY systems,” Referring to Cr—N, “At high T and high N content the gas pressure may be very large.”

Based on results from extensive autoclave testing described under “Experimental” hereinbelow, the ceramic compounds CrN, Cr₂N, and CrWN have been identified as behaving very well in both BWR conditions and high oxygen PWR operating conditions. CrZrN has been shown in other applications to have good oxidation resistance and it is believed that CrZrN will also behave very well in both BWR conditions and high oxygen PWR operating conditions. (See, K. Bouzid, N. E. Beliardouh, C. Noveau, “Wear and corrosion resistance of Cr—N based coatings deposited by RF magnetron sputtering”, HAL Id: hal-01202851 https://hal.archives-ouvertes.fr/hal-01202851, Submitted on 20 Jun. 2017, which provides an analysis of the corrosion and wears resistance performance of a single-layer of CrN coating deposited by reactive electron beam PVD).

Following the deposition of either or both of the outer coaling and intermediate layers, the method may further include annealing the layers. Annealing modifies mechanical properties and microstructure of the layers. Annealing involves heating the layers in the temperature range of 200° C. to 800° C., and preferably between 350° C. to 550° C. It relieves the stresses in the layers and imparts ductility which is necessary to sustain internal pressure in the cladding. As the cladding tube bulges, the layers should also be able to bulge.

The outer coaling and intermediate layers may also be ground., buffed, polished, or treated by other known techniques to achieve a smoother surface finish.

Various aspects of the subject matter described herein are set out in the following examples.

Example 1—A nuclear fuel cladding tube comprising:

a zirconium alloy tube having an outer wear and oxidation resistant coating selected from the group consisting of CrN, Cr₂N, CrWN, CrZrN, and combinations thereof.

Example 2—The nuclear fuel cladding recited in Example 1 wherein, the outer coating is between 0.1 and 30 μm in thickness.

Example 3—The nuclear fuel cladding recited in Example 1 or 2 further comprising:

an intermediate layer formed between the tube and the outer coating selected from the group consisting of Ta, W, Mo, Nb, and combinations thereof.

Example 4—The nuclear fuel cladding recited in Example 3 wherein, the intermediate layer is between 0.01 and 10 μm in thickness.

Example 5—The nuclear fuel cladding recited in Example 3 or 4 wherein, the intermediate layer is applied by physical vapor deposition.

Example 6—The nuclear fuel cladding recited in any one of Examples 1-5 wherein, the outer coating is applied by physical vapor deposition.

Example 7—A method for making a nuclear fuel cladding comprising:

providing a zirconium alloy cladding tube having an interior for housing fissile material and an exterior surface; and,

depositing a ceramic wear and oxidation resistant coating on the exterior surface of the cladding tube selected from the group consisting of CrN, Cr₂N, CrWN, CrZrN, and combinations thereof.

Example 8—The method recited in Example 7, wherein the ceramic coating is between 0.1 and 30 μm in thickness.

Example 9—The method recited in Example 7 or 8, Wherein the ceramic coating is deposited by physical vapor deposition

Example 10—The method recited in any one of Examples 7-9 further comprising:

depositing an intermediate layer on the exterior surface of the cladding tube prior to depositing the ceramic coating, the intermediate layer selected from the group consisting of Ta, W, Mo, Nb, and combinations thereof.

Example 11—The method recited in Example 10, wherein the intermediate layer is deposited by physical vapor deposition.

Example 12—The method recited in Example 10 or 11, wherein the intermediate layer is between 0.01 and 10 μm in thickness.

### EXPERIMENTAL

BWR conditions were simulated to determine which coatings did not corrode, or oxidize. The stability of the hard facing coating was evaluated by performing destructive testing before and after exposure in an autoclave. Oxygenated water was chosen as the oxidant to simulate an oxidizing BWR environment at 360° C.

The autoclave conditions were selected to be representative of commercial BWRs, with a level of oxygen that can promote corrosion in “poor” coatings as a good screening test for which materials will perform well in commercial plants. The autoclave used fix the exposure of the specimens consisted of a horizontal main body tube, approximately two meters long with an inner diameter of about ten cm, giving it an inner volume of roughly seven liters. The autoclave was connected to a once-through circuit which continuously refreshes the exposure chemistry and was equipped with basic instrumentation for monitoring the exposure, i.e. conductivity meters and thermocouples. Table 1 identifies the parameters measured during autoclave exposure and the target parameters.

TABLE 1
Measured parameters during the autoclave exposure

| Parameter | Target | | Comment |
|---|---|---|---|
| Temperature | 360° | C. | Autoclave inlet, |
| (° C.) | | | middle and outlet |
| Pressure | 215 bar | | Downstream autoclave |
| (bar) | (21,500 Pa) | | |
| Conductivity | >0.06 | μS/cm* | Upstream and downstream |
| (μS/cm) | | | autoclave |
| Flow rate | 31/h | | Manually at drain |
| (1/h) | | | |
| Oxygen level | 8 | ppm | Downstream autoclave |
| (ppb) | | | |
| Media | | | Ultrapure water with oxygen |
| Exposure time | 30 + 30 | days | |

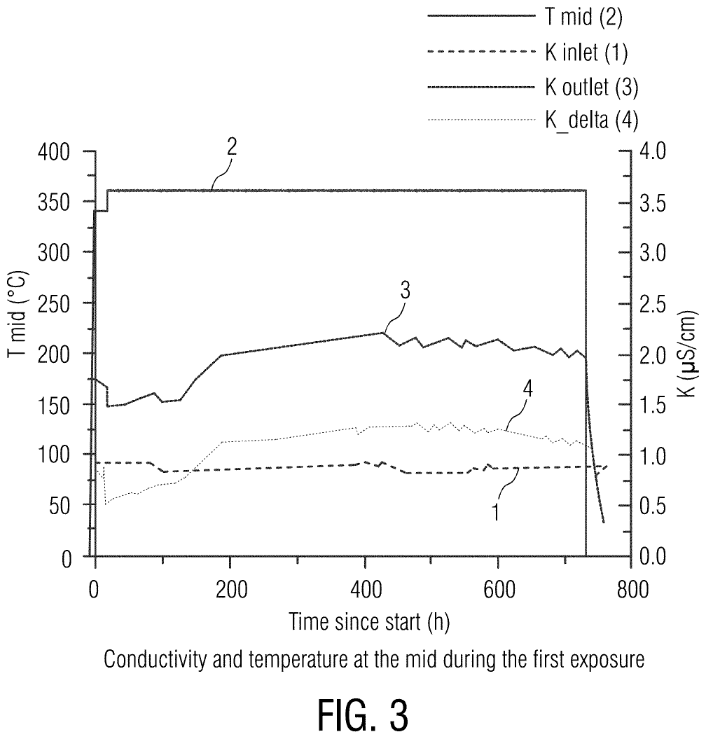

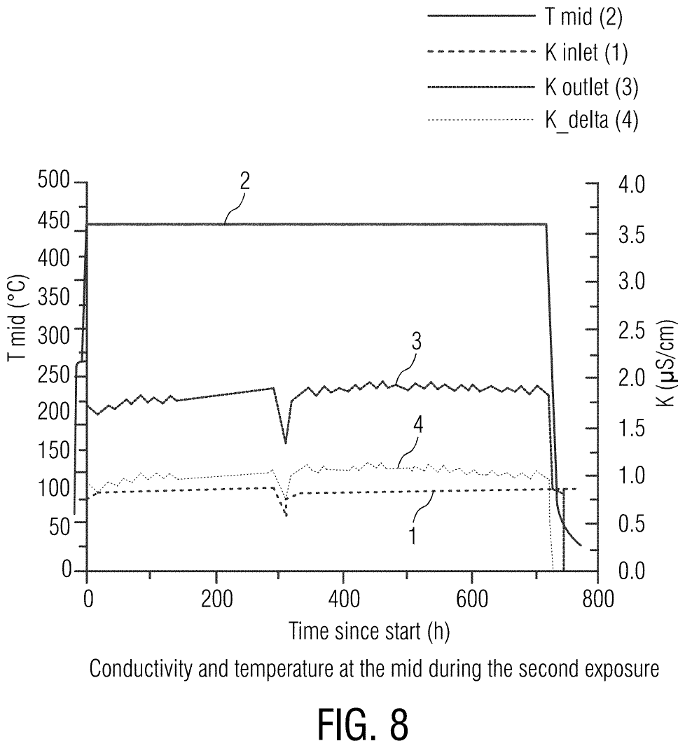

*conductivity was variable and generally higher. Conductivity at the inlet of the autoclave, after the mixing vessel, was noticeably high. Bypassing the mixing vessel using only ultrapure degassed water showed a decrease in conductivity to approximately 0.06 μS/cm but switching back to the technical air saturated water saw the increase again, even with replacement air tanks. See FIGS. 3 and 8.

Before starting the testing, the autoclave was pre-oxidized for approximately six weeks using 8 ppm oxygen (compressed air) at 340° C. Samples, in tubular and plate form, of a zirconium alloy coated with a hard facing coating were supplied as double samples, which were placed away from each other in the autoclave to examine or rule out any impact of corrosion from samples upstream. The samples were mounted on cassettes made of stainless steel, which also had been pre-oxidized together with the autoclave. The samples were suspended on zirconium alloy wire, which in turn was suspended in the cassettes by stainless steel wire. The three cassettes were placed around the center of the autoclave to maintain a stable temperature. There were two exposures, each for 30 days with an interruption in between the first and second exposures. Some samples were removed, and new ones added, during this interruption.

A total of 50 samples were exposed to simulated. BWR, normal water chemistry conditions at elevated temperature to examine the stability of hard facing coatings on fuel cladding material. The samples were exposed for either 30 or 60 (30+30) days total. The samples were photographed before the exposure, after the interruption, and after the full 60-day exposure. Stereo optical microscopy (SOS) analyses using a Wild-Heerbrugg/M7A stereo optical microscope were performed to acquire optical images (not shown) of all specimens at higher magnification., The exposures were performed without any events occurring that are thought to have an impact on the quality of the results. Indications of corrosion or otherwise unstable behavior in simulated conditions are shown by one or more of the following: discoloration, local inhomogeneity, flaking of the coating, changes in surface roughness. The samples were also visually examined before and after exposures, and are being further examined directly. The samples with CrN, Cr₂N, CrWN, or CrZrN coatings were judged to be the best performing coatings in terms of visual inspection, uniform smooth coating without blotches or areas of discoloration. They were the most resistant and most unchanged under the simulated BWR conditions and therefore those most promising for use as coatings for Zr alloy cladding.

The pH was measured using an Orion Dual Star pH meter from Thermo Scientific with a combined pH glass electrode from Metrohm. Before the measurement a three-point calibration were performed with pH-buffer solutions from MERCK with pH 4.01, 7.00 and 10.00. A check of the calibration by measuring the buffer solution with pH 7.00 were done before the pH measurement of the sample was performed.

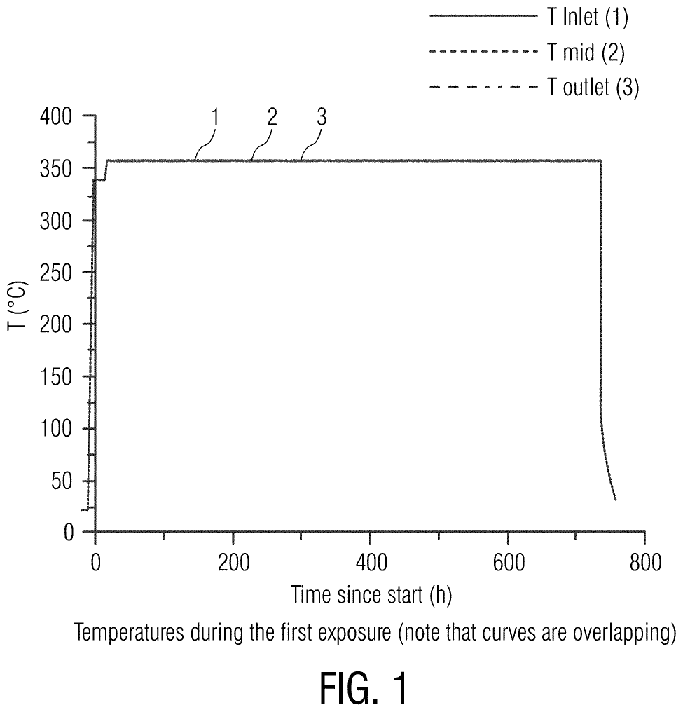

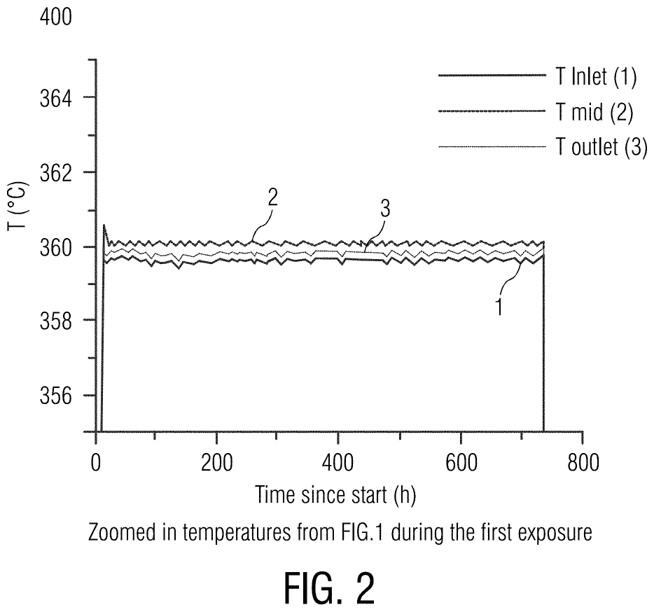

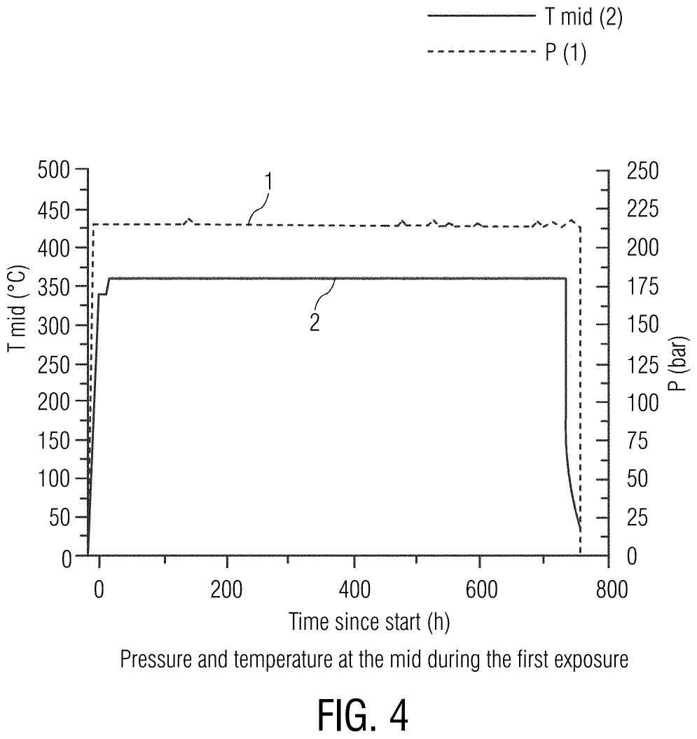

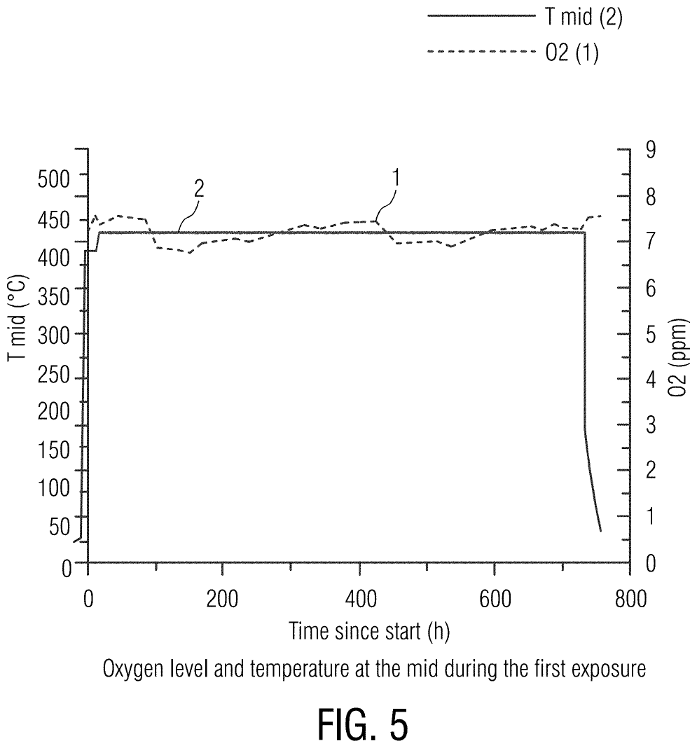

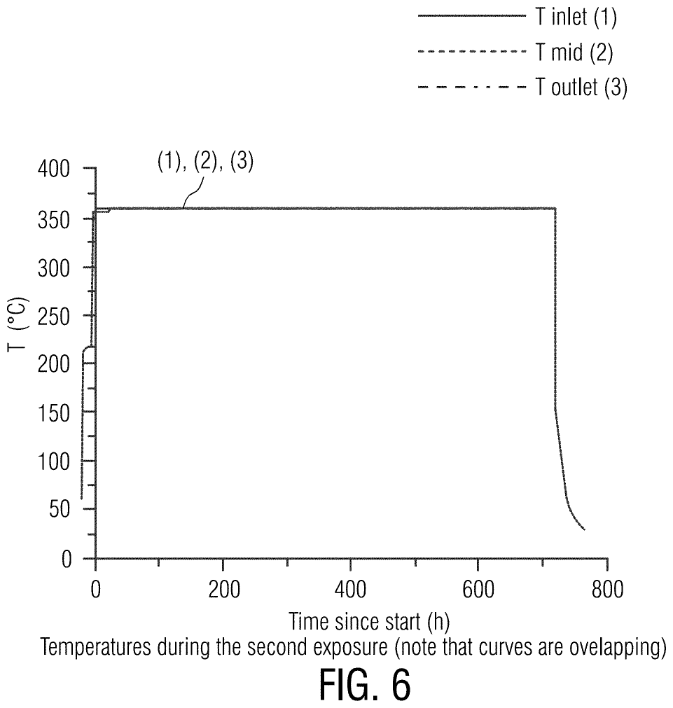

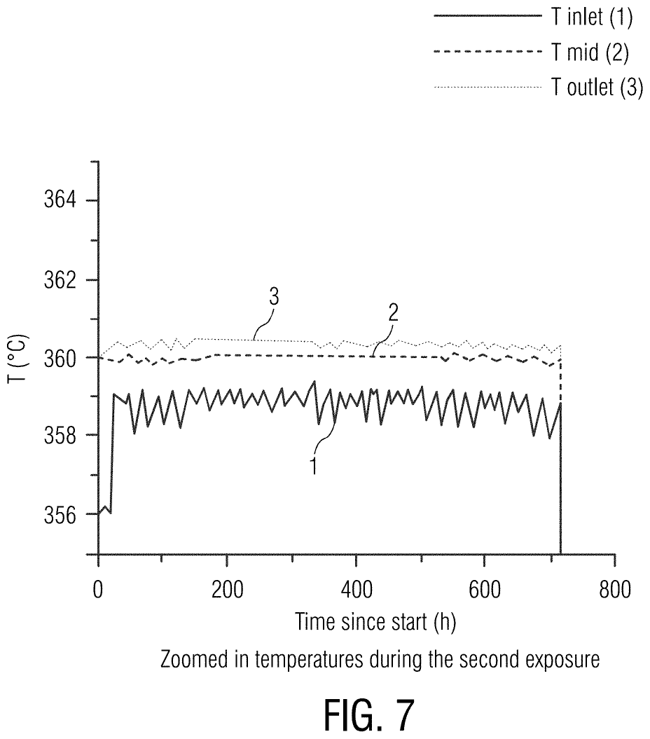

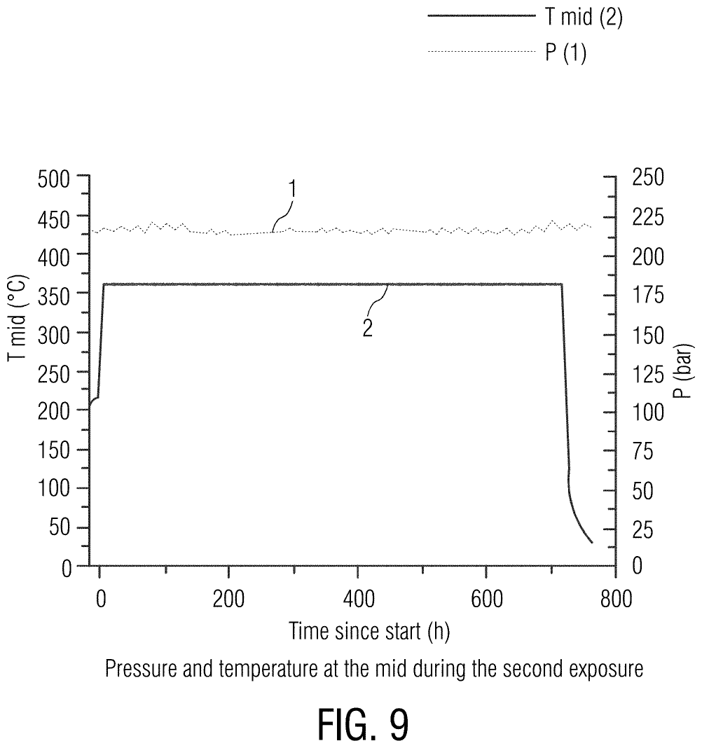

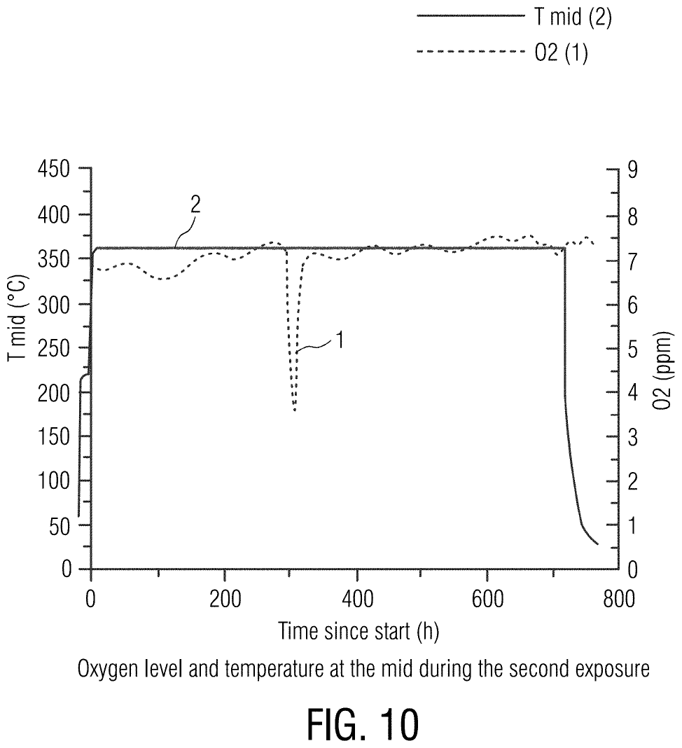

The autoclave temperature (inlet, middle and outlet), pressure, conductivity (inlet, outlet as well as increase) and oxygen for the first exposure is shown in FIG. 1-FIG. 5, While the same for the second exposure is shown in FIG. 6-FIG. 10. The first exposure was performed without any events while the second had two minor incidents, as follows:
1. No oxygen levels were measured during the warming sequence (from −20 to −2 hours before start in FIG. 10). This was due to the water being led to the drainage instead of to the analytical equipment. The oxygen saturation vessel was in operation during this time as normal, so the oxygen level in the water is believed to have been adequate during this time.
2. After approximately 300 hours, the oxygen level temporarily decreased, down to about half of the target value, due to a. malfunctioning valve in the saturation vessel, see FIG. 10 and FIG. 8. The impact this decrease has on the electrochemical potential is only minor.
   It was concluded that neither of the two above mentioned incidents have had any impact of the results or the quality of the results, and that exposure two, like exposure one, was completed successfully.

The ceramic compounds ON, Cr₂N, and CAM were identified based on the foregoing autoclave testing and determined to behave very well in both BWR conditions and high oxygen PWR operating conditions. It is believed that CrZrN, which has been shown to have good oxidation resistance in other applications, will also behave very well in both BWR conditions and high oxygen PWR operating conditions.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present invention has been described with reference to various exemplary and illustrative embodiments. The embodiments described herein are understood as providing illustrative features of varying detail of various embodiments of the disclosed invention; and therefore, unless otherwise specified, it is to be understood that, to the extent possible, one or more features, elements, components, constituents, ingredients, structures, modules, and/or aspects of the disclosed embodiments may be combined, separated, interchanged, and/or rearranged with or relative to one or more other features, elements, components, constituents, ingredients, structures, modules, and/or aspects of the disclosed embodiments without departing from the scope of the disclosed invention. Accordingly, it will be recognized by persons having ordinary skill in the art that various substitutions, modifications or combinations of any of the exemplary embodiments may be made without departing from the scope of the invention. In addition, persons skilled in the art will recognize, or be able to ascertain using no more than routine experimentation, many equivalents to the various embodiments of the invention described herein upon review of this specification. Thus, the invention is not limited by the description of the various embodiments, but rather by the claims.

What is claimed is:

1. A nuclear fuel cladding tube comprising:
a zirconium alloy tube having an outer wear and oxidation resistant coating selected from the group consisting of CrN, Cr₂N, CrWN, CrZrN, and combinations thereof

2. The nuclear fuel cladding recited in claim 1 wherein, the outer coating is between 0.1 and 30 μm in thickness.

3. The nuclear fuel cladding recited in claim 1 further comprising:
an intermediate layer formed between the tube and the outer coating selected from the group consisting of Ta, W, Mo, Nb, and combinations thereof.

4. The nuclear fuel cladding recited in claim 3 wherein, the intermediate layer is between 0.01 and 10 μm in thickness.

5. The nuclear fuel cladding recited in claim 3 wherein, the intermediate layer is applied by physical vapor deposition.

6. The nuclear fuel cladding recited in claim 1 wherein, the outer coating is applied by physical vapor deposition.

7. A method for making a nuclear fuel cladding comprising:
providing a zirconium alloy cladding tube having an interior for housing fissile material and an exterior surface; and,
depositing a ceramic wear and oxidation resistant coating on the exterior surface of the cladding tube selected from the group consisting of CrN, Cr₂N, CrWN, CrZrN, and combinations thereof.

8. The method recited in claim 7, wherein the ceramic coating is between 0.1 and 30 μm in thickness.

9. The method recited in claim 7, wherein the ceramic coating is deposited by physical vapor deposition.

10. The method recited in claim 7 further comprising:
depositing an intermediate layer on the exterior surface of the cladding tube prior to depositing the ceramic coating, the intermediate layer selected from the group consisting of Ta, W, Mo, Nb, and combinations thereof.

11. The method recited in claim 10, wherein the intermediate layer is deposited by physical vapor deposition.

12. The method recited in claim 10, wherein the intermediate layer is between 0.01 and 10 μm in thickness.
